(19) United States
(12) Patent Application Publication
(10) Pub. No.: US 2007/0045607 A1
(43) Pub. Date: Mar. 1, 2007

(54) Algainn nitride substrate structure using tin as buffer layer and the manufacturing method thereof

(76) Inventors: Nai-Chuan Chen, Tao-Yuan (TW); Chin-An Chang, Tao-Yuan (TW); Pen-Hsiu Chang, Tao-Yuan (TW); Chuan-Feng Shih, Tao-Yuan (TW); Wei-Chieh Lien, Tao-Yuan (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/211,673

(22) Filed: Aug. 26, 2005

(51) Int. Cl. H01L 31/00; H01L 21/00

(52) U.S. Cl. 257/14; 438/46; 257/190; 257/E33.008

(57) ABSTRACT

The present invention discloses a AlGaInN nitride substrate structure using TiN as buffer layer and the manufacturing method thereof. The present invention deposits TiN having (111) surface onto the silicon substrate having (111) surface as a buffer layer, and grows III-V AlGaInN nitride epitaxy structure having (0001) surface. The present method can form high-quality III-V AlGaInN nitride epitaxy layer to manufacture the vertical-conducted III-V AlGaInN nitride devices and utilize the high-reflection TiN surface to enhance the efficiency of the opti-electrical devices. The present invention can further prevent the silicon substrate forming the noncrystalline SiNₓ in the AlGaInN epitaxy process, so that the yield of the chip can be improved.

### BACKGROUND OF INVENTION

1. Field of the Invention

The invention relates to a III-V AlGaInN nitride substrate structure using silicon as substrate and the manufacturing method thereof, and more particularly, to a III-V AlGaInN nitride substrate structure using TiN as buffer layer and the manufacturing method thereof.

2. Description of the Prior Art

Since the III-V nitride materials have direct band-gap energy, the adjustable energy gap in AlGaInN can be from 0.7 eV to 6.2 eV by modulating the proportion of Al, Ga and In in AlGaInN. The range includes the wave band from the ultrared light to the ultraviolet light, and is suitable to the opticalelectric devices. However, since the shortage of substrate matching the crystal lattice, the epitaxy film for devices can not be manufactured even GaN was composed since 1970s. In the late 1980s, since the progress of the epitaxy technology of the III-V nitride materials, the high quality III-V nitride film is successfully grown on the sapphire (Al₂O₃) substrate, and the application of the III-V nitride materials is therefore developed. Nowadays, the III-V nitride material is popularly applied on the general blue, green or white light LEDs, light source of the cell phone panel or keypad, large dynamic bulletin board, or the traffic signals. In the near future, the III-V nitride material will be expectably applied to the laser light source of the CD-ROM driver, the backlight of LCD panel, or any general light source in our everyday life.

However, although the application of the III-V nitride material is very extensive, material of the epitaxy substrate has only little improvement and is generally commercialized based on the sapphire substrate. The sapphire substrate has some disadvantages: (1) It is too expensive. (2) Generally, diameter of the sapphire substrate is two inches and is too small to lower the manufacturing cost. (3) The sapphire substrate is an insulating material. If it is used for manufacturing the LED chip, the electrodes would be a horizontal structure and p and n electrodes have to be on same side. This feature will increase the manufacturing complexity, lower the yield and increase the cost. (4) Ability of heat dissipation of the sapphire substrate is bad, and this feature limits the application on high-power devices.

Besides the sapphire substrate, some commercialized products also use SiC as substrate. Comparing the SiC and sapphire substrates, the SiC substrate has two advantages: (1) SiC is a conductive material and can be used for forming the vertical-conducted devices. (2) Ability of heat dissipation is good. However, the SiC material has a critical disadvantage that the price is much higher than that of sapphire. Therefore, many research institutes try to use Si as the epitaxy substrate of the III-V nitride material.

Using Si as the epitaxy substrate of the III-V nitride material has the following advantages: (1) It's a conductive substrate (so the process can be simplified and the cost can be lowered). (2) It has a good heat conduction feature (1.5 W-cm⁻¹ that can be applied on high-power devices). (3) Large size (the diameter can be 12 inches now). (4) The conventional Si semiconductor technology can be also used.

Please refer to FIG. 1. Since the III-V nitride material is a rhombohedral wurtzite structure, it is different from the cubic diamond structure of the Si substrate. If the III-V nitride film is desired to grow on the Si substrate, silicon wafer 10 with Miller indices (111) must be selected and the III-V AlGaInN nitride 14 with indices (0001) is then grown on it. However, the lattice constants of the silicon (111) surface and the III-V AlGaInN nitride (0001) surface are much different. For example on GaN, the unmatched degree between the lattices is 16.95%, so a buffer layer 12 must be formed on silicon in advance and the required nitride film is then manufactured to overcome the stress issue. The structure is shown in FIG. 1. However, the most effective buffer layer is AlN or AlGaN. AlN is an insulation material and AlGaN acts between semiconductor and insulation depending on the ingredient. That will raise the resistance between lower structure of device (such as n-type GaN film) and Si substrate. When manufacturing the vertical-conducted device, the operation voltage must be substantially raised because of the series resistance in buffer layer. Besides, when growing AlN buffer layer on the silicon substrate, the source of N is generally from NH₃. However, NH₃ is easily combined with Si and becomes the noncrystalline SiNₓ. This film will affect the forming of high-quality epitaxy.

In addition, while forming LED on the silicon substrate, the energy gap of Si is only 1.12 eV, and the Si substrate could be a light absorption material comparing to the visible or ultraviolet light emitting from the the III-V nitride LED. After the photons are produced by the illuminating layer, its direction could be forward the silicon substrate, and only few photons could be reflected in the interface of silicon substrate and nitride. The other un-reflected photons will be absorbed by the silicon substrate and become heat, and that will lower the external quantum effect of the LED. FIG. 2 is a simulation of the reflection ratio of the light vertically emitting into the GaN and silicon substrate. In FIG. 2, when the light wavelength is 360 nm, the refection ratio is only 23%. With increasing the wavelength, the reflection ratio is descending, and the refection ratio is only 7.6% with wavelength 530 nm green light.

Hence, the present invention discloses a III-V AlGaInN nitride substrate structure using TiN as buffer layer and the manufacturing method thereof to solve the above problems of unmatched lattice and low reflection ratio.

### SUMMARY OF INVENTION

It is therefore a primary objective of the claimed invention to provide a AlGaInN nitride substrate structure using TiN as buffer layer and the manufacturing method thereof, in which the lattice matching between TiN and III-V AlGaInN nitride is higher and high-quality III-V AlGaInN nitride can be grown on the TiN buffer layer.

It is therefore another objective of the claimed invention to provide a AlGaInN nitride substrate structure using TiN as buffer layer and the manufacturing method thereof, in which, with the TiN buffer layer, the material NH₃ can be prevented from directly contacting the silicon substrate and forming the noncrystalline SiNₓ, so that the epitaxy will be successfully improved.

It is therefore a further objective of the claimed invention to provide a AlGaInN nitride substrate structure using TiN as buffer layer and the manufacturing method thereof, in which, since the TiN buffer layer has high conductivity, so that the current can flow from the III-V AlGaInN nitride epitaxy layer through the TiN buffer layer and then to the silicon substrate, and form the vertical-conducted III-V AlGaInN nitride devices.

It is therefore a further objective of the claimed invention to provide a AlGaInN nitride substrate structure using TiN as buffer layer and the manufacturing method thereof, in which the TiN buffer layer has a high reflection ability so that can improve the efficiency of the III-V AlGaInN nitride opti-electrical devices.

According to the claimed invention, an AlGaInN nitride substrate structure using TiN as buffer layer comprises a silicon substrate, Miller indices of the silicon substrate is (111); a TiN buffer layer locating on surface of the silicon substrate, Miller indices of the TiN buffer layer is (111); and at least one Alₓ(Ga_{y}In_{1-y})₁₋ₓN nitride layer locating on the TiN buffer layer, Miller indices of the Alₓ(Ga_{y}In_{1-y})₁₋ₓN nitride layer is (0001).

According to the claimed invention, a manufacturing method of AlGaInN nitride substrate structure using TiN as buffer layer comprises providing a silicon substrate, Miller indices of the silicon substrate is (111); forming a TiN buffer layer on surface of the silicon substrate, Miller indices of the TiN buffer layer is (111); and forming at least one Alₓ(Ga_{y}In_{1-y})₁₋ₓN nitride layer on the TiN buffer layer, Miller indices of the Alₓ(Ga_{y}In_{1-y})₁₋ₓN nitride layer is (0001).

These and other objectives of the present invention will no doubt become obvious to those of ordinary skill in the art after reading the following detailed description of the preferred embodiment that is illustrated in the various figures and drawings.

### BRIEF DESCRIPTION OF DRAWINGS

FIG. 1 is a schematic diagram of forming III-V AlGaInN nitride epitaxy layer on the silicon substrate according to the prior art.

FIG. 2 is a relationship diagram of the reflection ratio and the wavelength of the III-V AlGaInN nitride devices shown in FIG. 1.

FIG. 3 is a schematic diagram of the III-V AlGaInN nitride epitaxy crystalline according to the present invention.

FIG. 4(a) to 4(d) are schematic diagrams of the processing procedure of the III-V AlGaInN nitride LED according to the present invention.

FIG. 5 is a relationship diagram of the reflection ratio and the wavelength of the III-V AlGaInN nitride devices according to the present invention.

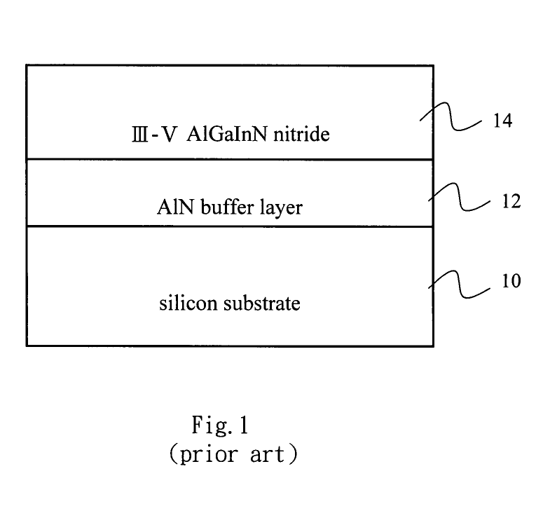

10 silicon substrate
12 buffer layer
14 III-V AlGaInN nitride
20 silicon substrate
22 TiN buffer layer
24 n-type GaN layer
26 multiple quantum well illuminating layer
28 electron barrier layer
30 p-type GaN layer
32 n-type electrode
34 p-type electrode

### DETAILED DESCRIPTION

The present invention relates to a AlGaInN nitride substrate structure using TiN as buffer layer and the manufacturing method thereof.

The optical devices formed by III-V AlGaInN nitride epitaxy can be classified into LED, laser diode, optical detecting diode and so on, and, in this embodiment, the III-V AlGaInN nitride LED is used for explaining the present invention. The present invention uses TiN as buffer layer to grow AlGaInN nitride on the silicon substrate and form optical devices having lattice matching and effective illumination.

First of all, the material character of TiN must be explained. TiN has golden color, high conductivity, high hardness, and high chemical stability. Its crystal formation is a cubic rocksalt structure with a lattice constant 0.4241 nm, and the lattice unmatched degree of its (111) surface and the (0001) surface of GaN is only 6.34%. So TiN is a great buffer layer matching the (111) surface of the silicon substrate and the (0001) surface of the III-V AlGaInN nitride.

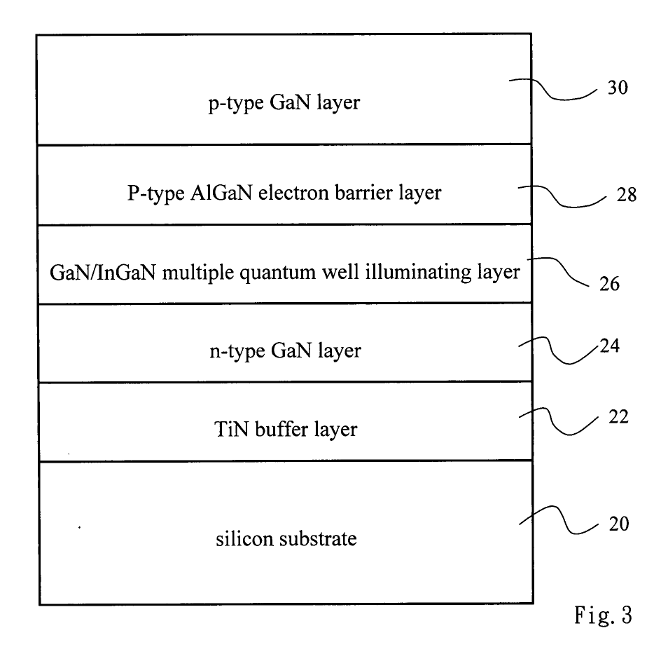

Please refer to FIG. 3, which is a schematic diagram of the III-v AlGaInN nitride epitaxy crystalline according to the present invention. The present invention includes a n-type silicon substrate 20 whose Miller indices is (111); a TiN buffer layer 22 locating on surface of the silicon substrate 20, Miller indices of the TiN buffer layer 22 is (111); at least one Alₓ(Ga_{y}In_{1-y})₁₋ₓN n-type nitride layer 24, such as GaN, locating on the TiN buffer layer 22, Miller indices of the Alₓ(Ga_{y}In_{1-y})₁₋ₓN n-type nitride layer 24 is (0001); a multiple quantum well illuminating layer 26 locating on the nitride layer, the multiple quantum well illuminating layer 26 is formed by epitaxy growing GaInN and GaN; a p-type AlGaN electron barrier layer 28 locating on the multiple quantum well illuminating layer 26; and a p-type GaN layer 30 locating on the electron barrier layer 28.

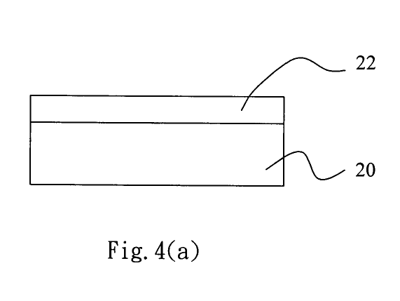

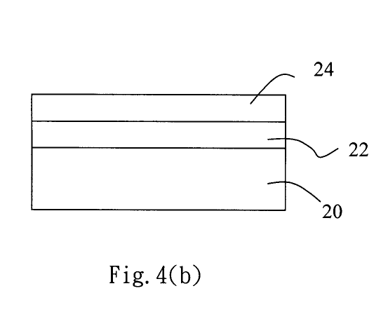

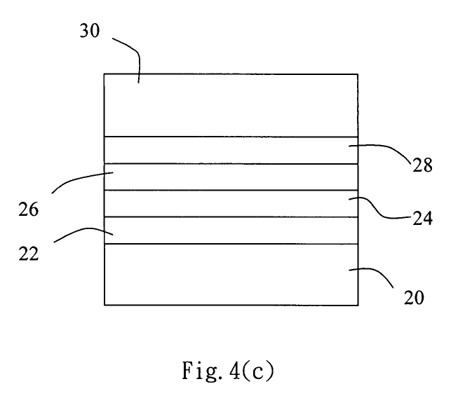

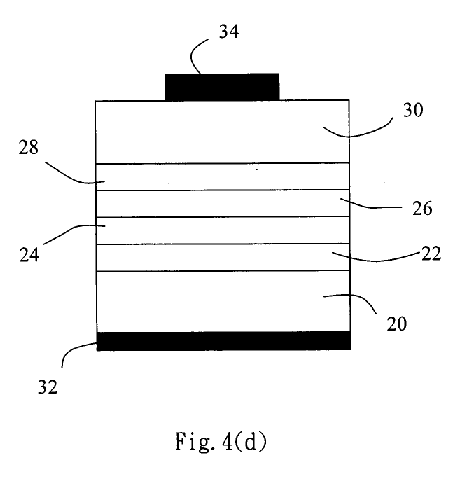

Please refer to FIG. 4(a) to 4(d), which are schematic diagrams of the processing procedure of the III-V AlGaInN nitride LED according to the present invention. In FIG. 4(a), a n-type silicon wafer is provided as a silicon substrate 20, Miller indices of the silicon substrate is (111). After removing the oxide layer on the silicon substrate 20, a TiN buffer layer 22 is formed on surface of the silicon substrate 20 by using sputter, physical vapor deposition (PVD), chemical vapor deposition (CVD), or metal organic chemical vapor deposition (MOCVD) methods, and Miller indices of the TiN buffer layer 22 is (111). Since TiN has high conductive electron concentration and the resistance can be as low as 50 μΩ·cm, it can form a great ohmic contact surface with the silicon substrate 20. In addition, since TiN has high conductive electron concentration, so the golden surface of the TiN buffer layer 22 can be a reflection surface of the opti-electrical device.

Then, as shown in FIG. 4(b), after completing coating the TiN buffer layer 22, a n-type GaN layer 24 with indices (0001) is grown on it. Since the lattice unmatched degree between the (111) surface of TiN buffer layer 22 and the (0001) surface of GaN layer 24 is only 6.34%, the high-quality GaN film can be obtained. Furthermore, the GaN layer 24 is n-type and can form a great ohmic contact with the TiN buffer layer 22 having high conductive electron concentration. After completing the vertical-conducted devices, the current will flow from the n-type GaN layer 24 through TiN buffer layer 22 to the silicon subtrate 20 without any high-resistance element.

Besides the above-mentioned advantages, surface of the silicon wafer is fully covered by the TiN buffer layer 22 before growing the GaN layer 24, so the material NH₃ of GaN will not directly contact the silicon substrate 20 and can avoid the forming of noncrystalline SiNₓ and improve the epitaxy success.

Furthermore, other AlGaInN nitride layer (not shown) can be further added between the GaN layer 24 and the TiN buffer layer 22 to further improve the quality of the GaN film.

Please refer to FIG. 4(c), after completing growing the n-type GaN layer 24, the multiple quantum well illuminating layer 26 formed by GaInN and GaN is grown on it, and the p-type AlGaN electron barrier layer 28 is later formed on the multiple quantum well illuminating layer 26. Finally, the p-type GaN layer 30 is grown and achieves a chip of III-V AlGaInN nitride LED as shown in figure. The n-type electrode 32 and the p-type electrode 34 are then formed on outer surfaces of the silicon substrate 20 and the p-type GaN layer 30 to complete the LED structure shown in FIG. 4(d).

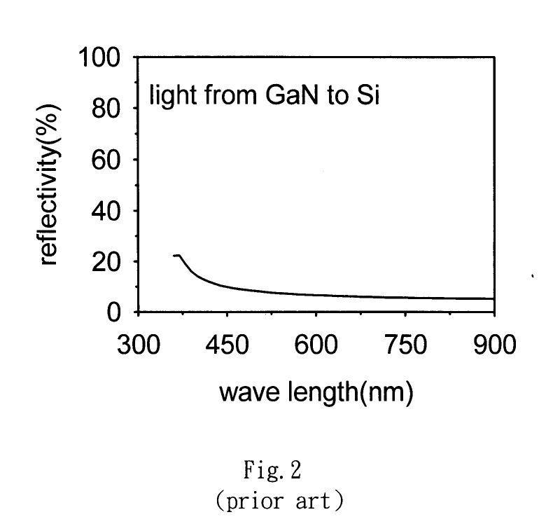

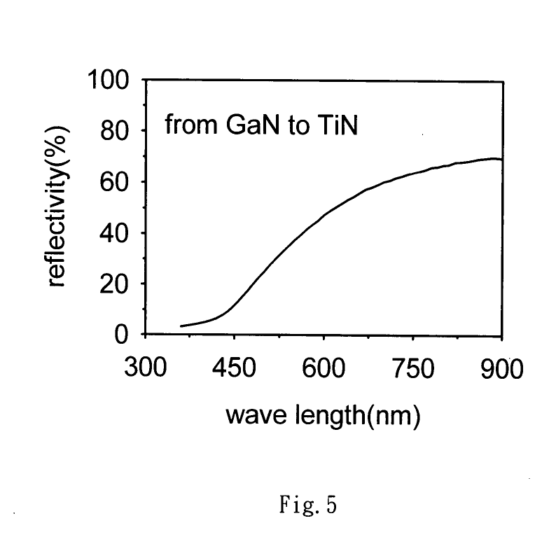

Please refer to FIG. 4(d) and FIG. 5, when the current flows from p-type electrode 34, through the p-type GaN layer 30, the p-type AlGaN electron barrier layer 28, the multiple quantum well illuminating layer 26 formed by GaInN and GaN, the n-type GaN layer 24, TiN buffer layer 22 and n-type silicon substrate 20, to the n-type electrode 32, the light will spontaneously emit from the multiple quantum well illuminating layer 26. The principle of light illumination is spontaneous irradiation and the light will emit toward all directions, so some proportion of light will go downward. The downward light passes through the n-type GaN layer 24 to the TiN buffer layer 22. FIG. 5 is a relationship diagram of the reflection ratio and the wavelength of the III-V AlGaInN nitride devices according to the present invention. After comparing FIG. 5 with FIG. 2, we can find that, when wavelength is larger than 450 nm, the reflection ability of TiN is greater than that of silicon and the difference is as obvious as wavelength increasing. Hence, if the light wavelength is higher than 450 nm, TiN will reflect partial light to upward direction and improve the illumination efficiency of the III-V AlGaInN nitride LED.

In conclusion, the present invention is the AlGaInN nitride substrate structure using TiN as buffer layer and the manufacturing method thereof. The present invention is based on the following principles that TiN and III-V AlGaInN nitride have great lattice matching so that can form high-quality III-V AlGaInN nitride, TiN and silicon substrate have great ohmic contact surface and can protect the silicon substrate from contacting NH₃ while forming III-V AlGaInN nitride, and TiN gas a high reflection so that can reflect the spontaneous-irradiation light backward to enhance the illumination efficiency of the III-V AlGaInN nitride LED and lower the manufacturing cost. The opti-electrical devices made by the present invention can have a great competitiveness in the marketplace.

Those skilled in the art will readily observe that numerous modifications and alterations of the device may be made while retaining the teachings of the invention. Accordingly, the above disclosure should be construed as limited only by the metes and bounds of the appended claims.

What is claimed is:

1. An AlGaInN nitride substrate structure using TiN as buffer layer, comprising:
a silicon substrate, Miller indices of the silicon substrate is (111);
a TiN buffer layer locating on surface of the silicon substrate, Miller indices of the TiN buffer layer is (111); and
at least one Alₓ(Ga_{y}In_{1-y})₁₋ₓN nitride layer locating on the TiN buffer layer, Miller indices of the Alₓ(Ga_{y}In_{1-y})₁₋ₓN nitride layer is (0001).

2. The AlGaInN nitride substrate structure using TiN as buffer layer of claim 1, wherein the TiN buffer layer is formed by using sputter method.

3. The AlGaInN nitride substrate structure using TiN as buffer layer of claim 1, wherein the TiN buffer layer is formed by using physical vapor deposition method.

4. The AlGaInN nitride substrate structure using TiN as buffer layer of claim 1, wherein the TiN buffer layer is formed by using chemical vapor deposition method.

5. The AlGaInN nitride substrate structure using TiN as buffer layer of claim 1, wherein the TiN buffer layer is formed by using metal organic chemical vapor deposition method.

6. The AlGaInN nitride substrate structure using TiN as buffer layer of claim 1, wherein thickness of the TiN buffer layer is 5 nm to 10 μm.

7. The AlGaInN nitride substrate structure using TiN as buffer layer of claim 1, wherein after forming the TiN buffer layer, the TiN buffer layer can be performed a thermal annealing process to improve crystallization and conductivity.

8. The AlGaInN nitride substrate structure using TiN as buffer layer of claim 7, wherein temperature of the thermal annealing process is 200° C. to 1200° C., and air used in the thermal annealing process can be selected from nitrogen, ammonia, inert gas, vacuum or oxygen-free environment composed of combination of these gases.

9. The AlGaInN nitride substrate structure using TiN as buffer layer of claim 1, wherein in formation of Alₓ(Ga_{y}In_{1-y})₁₋ₓN, x is from 0 to 1 and y is from 0 to 1.

10. The AlGaInN nitride substrate structure using TiN as buffer layer of claim 1, wherein Alₓ(Ga_{y}In_{1-y})₁₋ₓN can be formed by film of single element or films stacked by several elements.

11. The AlGaInN nitride substrate structure using TiN as buffer layer of claim 1, wherein the silicon substrate can be n type, p type or semi-insulation type.

12. A manufacturing method of AlGaInN nitride substrate structure using TiN as buffer layer, comprising:
providing a silicon substrate, Miller indices of the silicon substrate is (111);
forming a TiN buffer layer on surface of the silicon substrate, Miller indices of the TiN buffer layer is (111); and
forming at least one Alₓ(Ga_{y}In_{1-y})₁₋ₓN nitride layer on the TiN buffer layer, Miller indices of the Alₓ(Ga_{y}In_{1-y})₁₋ₓN nitride layer is (0001).

13. The manufacturing method of AlGaInN nitride substrate structure using TiN as buffer layer of claim 12, wherein the TiN buffer layer is formed by using sputter method.

14. The manufacturing method of AlGaInN nitride substrate structure using TiN as buffer layer of claim 12, wherein the TiN buffer layer is formed by using physical vapor deposition method.

15. The manufacturing method of AlGaInN nitride substrate structure using TiN as buffer layer of claim 12, wherein the TiN buffer layer is formed by using chemical vapor deposition method.

16. The manufacturing method of AlGaInN nitride substrate structure using TiN as buffer layer of claim 12, wherein the TiN buffer layer is formed by using metal organic chemical vapor deposition method.

17. The manufacturing method of AlGaInN nitride substrate structure using TiN as buffer layer of claim 12, wherein thickness of the TiN buffer layer is 5 nm to 10 μm.

18. The manufacturing method of AlGaInN nitride substrate structure using TiN as buffer layer of claim 12, wherein after forming the TiN buffer layer, the TiN buffer layer can be performed a thermal annealing process to improve crystallization and conductivity.

19. The manufacturing method of AlGaInN nitride substrate structure using TiN as buffer layer of claim 12, wherein temperature of the thermal annealing process is 200° C. to 1200° C., and air used in the thermal annealing process can be selected from nitrogen, ammonia, inert gas, vacuum or oxygen-free environment composed of combination of these gases.

20. The manufacturing method of AlGaInN nitride substrate structure using TiN as buffer layer of claim 12, wherein in formation of Alₓ(Ga_{y}In_{1-y})₁₋ₓN, x is from 0 to 1 and y is from 0 to 1.

21. The manufacturing method of AlGaInN nitride substrate structure using TiN as buffer layer of claim 12, wherein Alₓ(Ga_{y}In_{1-y})₁₋ₓN can be formed by film of single element or films stacked by several elements.

22. The manufacturing method of AlGaInN nitride substrate structure using TiN as buffer layer of claim 12, wherein the silicon substrate can be n type, p type or semi-insulation type.
